(19) United States
(12) Patent Application Publication
(10) Pub. No.: US 2025/0341567 A1
(43) Pub. Date: Nov. 6, 2025

(54) PLUGGABLE OPTICAL VOLTAGE AND CURRENT PROBES

(71) Applicant: Tektronix, Inc., Beaverton, OR (US)

(72) Inventor: Mark A. Norris, Louisville, CO (US)

(73) Assignee: Tektronix, Inc., Beaverton, OR (US)

(21) Appl. No.: 19/197,940

(22) Filed: May 2, 2025

Related U.S. Application Data
(60) Provisional application No. 63/641,870, filed on May 2, 2024.

(51) Int. Cl. G01R 31/311

(52) U.S. Cl. CPC G01R 31/311

(57) ABSTRACT

A test and measurement probe for measuring an electrical signal in a device under test (DUT) includes a probe body, a sensor head separate from the probe body, one or more transmission optical fibers to convey an optical measurement signal between the probe body and the sensor head, and a pluggable interface between the probe body and the sensor head. The probe body includes an optical source to produce the optical measurement signal, receiver circuitry to receive the optical measurement signal and convert the optical measurement signal to an electrical measurement signal, and a connector to output the electrical measurement signal to a test and measurement instrument. The sensor head includes one or more sensor head optical fibers configured to convey the optical measurement signal to cause the electrical signal in the DUT to modify a polarization state of the optical measurement signal.

### CROSS-REFERENCE TO RELATED APPLICATION

This application claims the benefit of U.S. Provisional Pat. App. No. 63/641,870, filed May 2, 2024, which is hereby incorporated by reference in its entirety.

### TECHNICAL FIELD

This disclosure relates to test and measurement systems, and more particularly to test and measurement probes.

### BACKGROUND

Users of test and measurement instruments, such as oscilloscopes, typically use a test and measurement probe as the interface between the test and measurement instrument and a device under test (DUT). Test and measurement probes are designed for particular measurement applications. For example, voltage probes are designed for measuring a voltage signal in a DUT. Voltage probes can be further sub-categorized into probes designed for measuring high voltages versus those designed for measuring low voltages, probes designed to measure single-ended signals versus probes designed to measure differential signals, etc. Likewise, current probes are designed for measuring a current signal in a DUT. Current probes can be further sub-categorized into supported ranges of minimum and maximum currents to be measured, different bandwidths of the measured current signal, single-ended versus differential, etc. Some probes, such as the Iso Vu™ series of isolated voltage and current probes from Tektronix, Inc., are designed to provide galvanic isolation between the DUT and the test and measurement instrument, meaning that there is no common ground and no current flow between the DUT and the instrument. This allows safe and accurate measurement of voltages and/or currents in the presence of large common mode signals in the DUT.

### BRIEF DESCRIPTION OF THE DRAWINGS

FIG. 1 is a block diagram of a test system according to embodiments of the disclosure.

FIG. 2 is a block diagram of a test and measurement probe using a fiber optic current sensor and linear polarization, according to embodiments of the disclosure.

FIG. 3 is a block diagram of a test and measurement probe using a fiber optic current sensor, circular polarization, and an interferometer, according to embodiments of the disclosure.

FIG. 4 is a block diagram of a test and measurement probe using a fiber optic current sensor, circular polarization, and a Sagnac interferometer, according to embodiments of the disclosure.

FIG. 5 is a block diagram of a test and measurement probe using a fiber optic current sensor, circular polarization, and a Sagnac interferometer, according to embodiments of the disclosure.

FIG. 6 is a block diagram of a test and measurement probe using a fiber optic current sensor, circular polarization, and a Sagnac interferometer separated into two portions, according to embodiments of the disclosure.

FIG. 7 is a block diagram of a test and measurement probe using a fiber optic voltage sensor including a Pockels cell, according to embodiments of the disclosure

### DETAILED DESCRIPTION

Fiber optic current measurement meets the requirements for measuring current under challenging conditions encountered in switching power applications as switching frequencies and power levels increase. Currently available fiber optic current sensors (FOCS) are targeted towards DC and AC grid applications. According to embodiments of the disclosure, FOCS can be built into test and measurement probes that can be used to acquire a signal from a device under test (DUT) and route the signal to an input of a test and measurement instrument, such as an oscilloscope, for example. One target application for FOCS-based probes are the active devices used in high power, high switching rate converters.

The following Figures of Merit for current probing solutions are of importance in high power switching applications to assess efficiency and reliability of the switching power supplies:
1. Electrical Isolation—Safety and grounding require electrical isolation. High power stacks converters to achieve high voltage operation, depending on the application up to megavolts.
2. Operation in Electrically Noisy Environments—High voltage slew rates couple noise into electrical circuits and create AC ground loops, disrupting or destroying measurements. The voltage slew rates are increasing as switching frequencies and power level increase, requiring greater immunity in the measurement sensors.
3. Low Insertion Parasitics—High switching frequencies and current/voltage slew rates necessitate compact designs that have minimal interconnect inductance. Increasing the inductance to enable room for or when making current measurements disrupts the circuit operation, causing additional ringing and inefficiencies. Similarly, metal in critical areas of the circuit increase capacitive coupling, disrupting circuit operation. Additional resistance for current measurement dampens ringing and decreases efficiency.
4. High Bandwidth—Accurately capturing ringing requires much higher bandwidth than even capturing the very high switching slew rates.
5. Fast Overload Recovery—Leakage current is much, much smaller than operating current and slow overload recovery can preclude or distort measurements after conduction periods.
6. Ease of Installation—Power supplies are becoming more compact, making it difficult to get the sensor into position for making measurements.
7. High Accuracy—Low hysteresis and high linearity are required to avoid distorting measurements.
8. Bipolar Operation with Stable Zero Point—Stability of the zero-reference point is of importance for correct interpretation of measurements.

High sensitivity can be a figure of merit for low current applications, but is generally not required in high power applications except for measuring leakage.

According to the above factors, current measurement using the Faraday effect in optical fibers compares favorably to other current sensing approaches for high power switching including the following technologies: ferrite ring with Hall/tunneling magnetoresistance (TMR) sensor, Rogowski coil with DC sense resistor with power over fiber, and TMR current sensing.

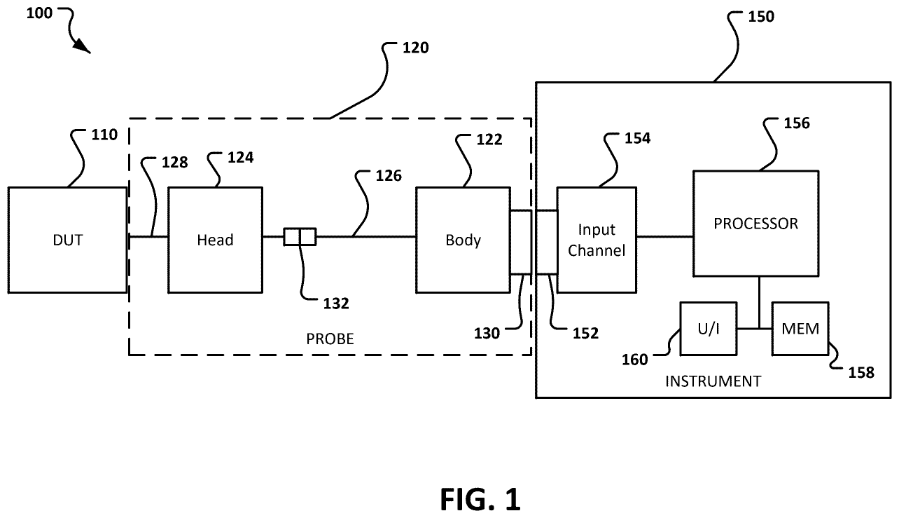

FIG. 1 is a block diagram of an example test system 100 according to embodiments of the disclosure. Test system 100 includes a device under test (DUT) 110, a test and measurement instrument 150, and a test and measurement probe 120 coupled between the test and measurement instrument and the DUT. The DUT may be any type of device that has voltage or current signals to be measured by the test system, i.e. by the combination of the probe 120 and the instrument 150. In some examples, the DUT may simply be a current-carrying conductor, such as a wire.

The instrument 150 generally includes an input connector 152 to electromechanically couple to the probe 120. The input connector provides an interface between the probe and the instrument, and generally includes an analog input signal path, such as a BNC connector, to receive an analog electrical output signal from the probe representative of the signal being measured in the DUT. But, in some examples, the input connector may also include one or more additional analog and/or digital connections to, for example, provide power to the probe 120, control and communication between the probe and the instrument, and other functions. In some examples, the input signal to the instrument is provided digitally by the probe.

The input signal from probe is typically routed through the input connector 152 to input channel circuitry 154. Input channel circuitry 154 may include filters, attenuators, amplifiers, offset control, and other signal conditioning circuitry, as well as one or more analog-to-digital converters (ADCs) to convert the analog input signal from the probe into an acquired digital waveform. Acquisition of the input signal may be controlled by one or more processors 156. The one or more processors 156 may perform triggering functions, further processing of the acquired digital waveform, such as through digital signal processing (DSP), etc.

The one or more processors 156 may operate according to instructions stored in a memory 158, which may also store one or more acquired waveforms. The instrument 150 also includes a user interface 160. The user interface can include input interfaces such as keyboards, mice, touchscreen, a programmatic interface, etc., to allow a user to control and operate the instrument, and the connected probe 120. The user interface can also include output interfaces, such as a display, to for example display an acquired waveform, such as the measured signal from the DUT.

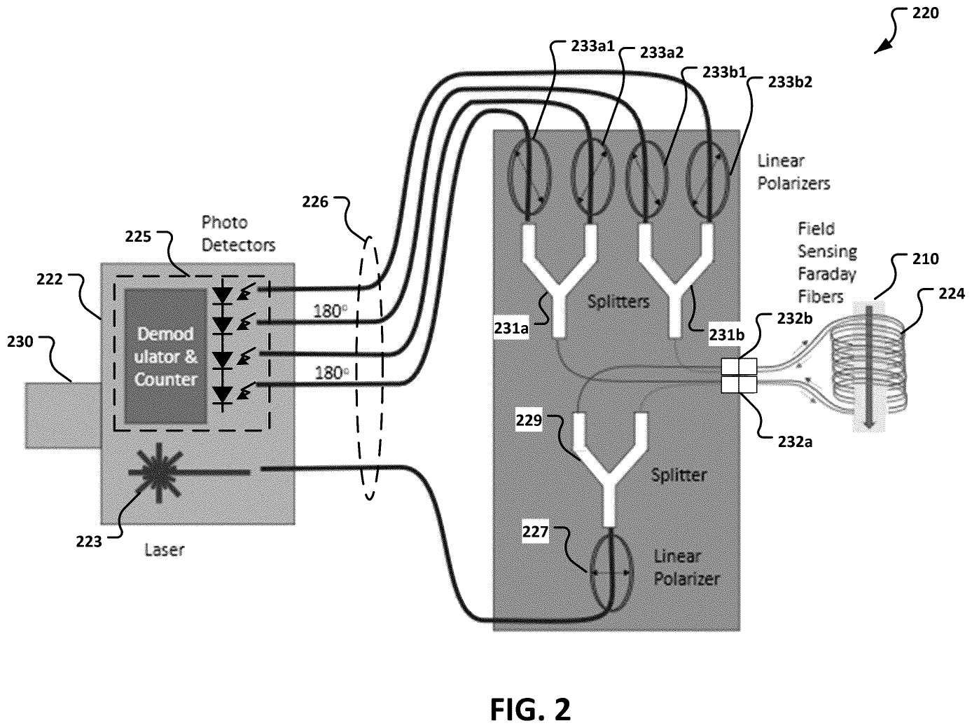

The probe 120, according to embodiments of the disclosure, includes a probe body 122, a sensor head 124, which is separate from the probe body, and a connection 126 between the probe body and the sensor head. The probe body 122 is enclosed in a housing, and, according to embodiments of the disclosure, includes most of the electrical components of the probe 120. As will be discussed further with respect to FIGS. 2-7, the probe body also includes an optical source, such as a laser, to produce an optical measurement signal, and receiver circuitry, including an optical receiver, to receive the optical measurement signal after it has been modified by influence of the signal in the DUT to be measured, and convert the modified optical measurement signal into an electrical measurement signal representative of the signal in the DUT to be measured. The probe body also includes an output connector 130, which interfaces with and connects to input connector 152 of the instrument 150 in order to output the electrical measurement signal to an input of the instrument 150. Thus, in operation, the probe body 122 is physically near the input connector 152 of the instrument 150. The connection 126 is typically relatively long and flexible, such as a cable, to allow the sensor head 124 to be conveniently located physically close to the DUT. According to embodiments of the disclosure, the connection 126 may include one or more optical signal paths, e.g. optical fibers, to convey the optical measurement signal between the probe body and the sensor head and vice versa. These one or more optical signal paths will be referred to as “transmission optical fibers.” And, according to some embodiments of the disclosure, the connection 126 may also include one or more electrical signal paths, e.g. wires.

The sensor head 124 has a coupling interface 128 to the DUT. According to some embodiments of the disclosure, in which the probe is used for measuring a voltage signal in the DUT, the coupling interface 128 may be, for example, a pair of leads to be connected, either permanently, or by temporary physical contact, to a voltage in the DUT to be measured, e.g. between two circuit nodes in the DUT. According to other embodiments of the disclosure, in which the probe is used for measuring a current signal in the DUT, the coupling interface 128 may be, for example, one or more optical fibers wrapped around a current-carrying conductor in the DUT so that one or more loops of optical fibers are exposed to the magnetic fields generated by the current-carrying conductor. These optical fibers will be referred to as “sensor head optical fibers.”

The probe may also include a pluggable interface 132 between the probe body 122 and the sensor head 124. The pluggable interface may comprise, for example, pairs of mating optical connectors for each one of the optical signal paths, and pairs of mating electrical connectors for each one of the electrical signal paths in the connection 126. The pluggable interface allows a user to disconnect the sensor head 124 from the rest of the probe 120. As discussed further below, this enables a user to, depending on the use case, wrap the sensor head around a conductor in the DUT, and/or leave the sensor head installed in the DUT. The pluggable interface 132 also allows the user to change from voltage to current measurement and change the sensitivity of their measurement, and could be sufficiently inexpensive that manufacturers can leave the sensors in manufactured units, e.g. DUTs. The transmission optical fibers may have different optical characteristics, for instance, low birefringence or phase maintain properties, than the sensor head optical fibers. According to some embodiments, the pluggable interface 132 may be keyed so the user can only use proper sensor heads. In some embodiments, the plug may also include a memory device (not shown), such as an EPROM, to store and provide gain information and/or other calibration information.

Probes according to embodiments of the disclosure, generally utilize a fiber optic current sensor. A FOCS generally operates by shining a polarized light beam through a suitable media such as an optical fiber which interacts with a magnetic field to rotate the polarization of the light as it passes through the fiber. This is effect is called the Faraday effect, and is caused by the interaction of the light with the electrons in the media causing a change in propagation velocity that is dependent on the direction of polarization of the light.

As the Faraday effect rotates the polarization of light through a medium, the polarization rotation is dependent on the strength of the magnetic field in the direction of travel of the wave through the medium and distance the light travels through the medium.

According to embodiments of the disclosure, wrapping a sensing fiber around an electrical conductor measures the entire magnetic flux generated by the current through the conductor; a closed circular path, thus measures the current.

The measurement sends a polarized beam of light, the polarization generated intrinsically by the source, or by filtering the source, through the fiber and measuring the shift in polarization. In one approach, the light is linearly polarized and the sensor measures output polarization by filtering output two separate channels with polarizers at right angles to each other. In the second approach, the light is circularly polarized, and the Faraday effect advances or retards the phase of the light. The sensor measures the change in polarization by an interferometer compared to an undelayed copy of the source.

The amount of Faraday effect is determined by the intrinsic properties of the fiber material and external influences. Fused silica, standard fiber optic cable, has a moderate Faraday effect. According to some embodiments of the disclosure, to cancel external effects to the Faraday effect such as pressure, temperature, strain etc., the sensor employs a second fiber run around in the opposite direction to the first fiber. The phase shift is opposite in the two fibers. The sensor looks at the difference in phase shift between the two fibers, which is twice that of a single fiber, and rejects the external influences which affect the polarization of both fibers equally.

The Faraday effect is inversely proportional to the wavelength of the light, so blue source has a greater Faraday effect than a red or infrared source.

Fused silica has a Verdet constant, a measure of the Faraday rotation per unit magnetic field per meter of waveguide length, of V=2.4 rad/T·m at 650 nm, with Terbium-doped fibers having 10× larger Verdet constant than silica.

$$θ = n \cdot ∮ V \cdot B \cdot dl = n \cdot V \cdot ∮ \frac{{μ}_{0} \cdot I}{2 π \cdot r} \cdot dl = {μ}_{0} \cdot V \cdot n \cdot I ≅ 3 {e}^{- 6} rad \cdot n \cdot I$$

$$\text{where:}$$

$$θ = Faraday Phase Shift$$

$$n = Number turns ( actual turns area twice due to counter wrapping )$$

$$I = Current in Amps$$

$$V = Verdet Constant of the material$$

$$B = Magnetic Field Strength in Tesla = \frac{{μ}_{0} \cdot I}{π \cdot r}$$

$$r = Radius of integration loop$$

$${μ}_{0} = Magnetic Permitivity = 4 π \cdot {10}^{- 1} T \cdot m / A$$

This analysis shows that the angles should be small, no un-wrapping required, and the small angle approximation for sin (θ)≅θ hold. The sensitivity will be low, requiring high gain that may limit bandwidth, and the use of doped fibers and short wavelength (blue) lasers should be employed to improve sensitivity. For currents ≥10 A, Faraday current sensors should give good quality measurements while employing a small number of turns.

To attain high isolation, probes, according to embodiments of the disclosure, locate all electrical components away from the device under test. These electrical components include the source, typically a laser, and the photodetectors. The optical components including polarizers, splitters, interferometer, etc. may be located with the electronics, or close to the device under test. Locating the measurement polarizers or interferometer near the device under test avoids pickup of differential phase shift; however, this configuration may be sensitive to differential signal loss on the fibers between the device under test and the electronics.

Furthermore, the sensor can employ the field sensing Faraday fibers in three different configurations depending on the application, according to various embodiments of the disclosure. In some embodiments, the sensor may permanently connect the fibers to the optical processing requiring the user to feed the current carrying conductor through the loops of fiber. In this configuration, the winding of the fiber bundle is maintained in a fixed configuration, improving measurement repeatability. In other embodiments of the disclosure, a second configuration has the fibers connected permanently only to one side of the optical processing, so the user can wind the fiber bundle around the conductor. In a third configuration, according to other embodiments of the disclosure, the fiber bundle is pluggable into the optical processing. This third configuration is low cost so users can permanently install the fibers into all deployed units. Permanently installing the fiber optics into the package or board (the DUT) enables easy installation. Once installed, routine maintenance can use the sensor to monitor reliability of the device under test.

Although directly digitizing all channels and digitally computing and potentially unwrapping the arctangent is the preferred method for computing the phase, analog approximations exist for this computation.

There is no way of “subtracting” light directly as there is no negative light. Using linearly polarized light requires demodulating the horizontal and vertical components of both the forward and counter path separately, and performing the subtraction in the electronics.

FIG. 2 is a block diagram of an example probe 220 using linear polarization according to some embodiments of the disclosure. In FIG. 2, the probe 220 is configured for measuring a current in DUT 210, which is a current-carrying conductor. In this case, the sensor head 224 is a current sensor head that includes a pair of sensor head optical fibers counter-wrapped around DUT. That is, one optical fiber of the pair of sensor head optical fibers is wrapped in one direction around the current-carrying conductor, and the other optical fiber of the pair is wrapped in the opposite direction around the current-carrying conductor, as shown in FIG. 2.

The probe 220 may include a pluggable interface 232a, 232b, at one or both ends of the sensor head optical fiber bundle. Having one pluggable interface at just one end of the sensor head optical fiber bundle, i.e. either 232a or 232b, allows a user to wrap the sensor head optical fibers around the DUT 210. Having a pluggable interface as both ends of the sensor head optical fiber bundle, i.e. both 232a and 232b, allows a user to even more easily wrap the sensor head optical fibers around the DUT 210, and also allows the user to fully disconnect the sensor head 224 from the rest of the probe 220, and to leave the sensor head installed in the DUT. Assuming the sensor heads 224 are sufficiently inexpensive, a user can leave multiple sensor heads 224 installed on various locations on a DUT, quickly connect the rest of the probe 220 to one of these installed sensor heads to measure a current at that location, and quickly switch between measurements at different locations. In some embodiments, the sensor head optical fiber bundle may also include another connector (not shown) that permits the user to wrap the sensor around the conductor DUT 210.

The probe 220 includes a probe body 222 which is enclosed in a housing. The probe body 222 includes an optical source 223, shown as a laser in FIG. 2. The probe body also includes receiver circuitry 225, which includes one or more optical receivers, shown as photodetectors in FIG. 2. And, the probe body includes connector 230, which is similar to connector 130 in FIG. 1. The probe 220 also includes one or more transmission optical fibers 226 between the probe body 222 and the sensor head 224.

The probe 220 uses linear polarization techniques. The optical source 223 produces an optical measurement signal, i.e. light, that is conveyed through one of the transmission optical fibers, a source fiber, to a linear polarizer 227. The polarized optical measurement signal is then split by a first splitter 229, and the two outputs of the splitter feed the optical measurement signal into the two counter-wrapped sensor head optical fibers. The current signal in the DUT modifies a polarization state of the optical measurement signal as it travels through the sensor head. The two modified optical measurement signals from each end of the sensor head 224 are then each fed into another splitter 231a, 231b. The two outputs from splitter 231a are fed through a pair of orthogonal linear polarizers 233a1, 233a2, i.e. linear polarizers oriented at 90 degrees to one another. The two outputs from splitter 231b are fed through another pair of orthogonal linear polarizers 233b1, 233b2. The outputs of the four linear polarizers 233a1, 233a2, 233b1, 233b2, are coupled to one of four receive optical fibers in the transmission optical fibers 226, which convey these four modified optical measurement signals back to photodetectors in the receive circuitry 225. The receive circuitry 225 then converts the optical measurement signals to an electrical measurement signal representative of the current in the DUT 210.

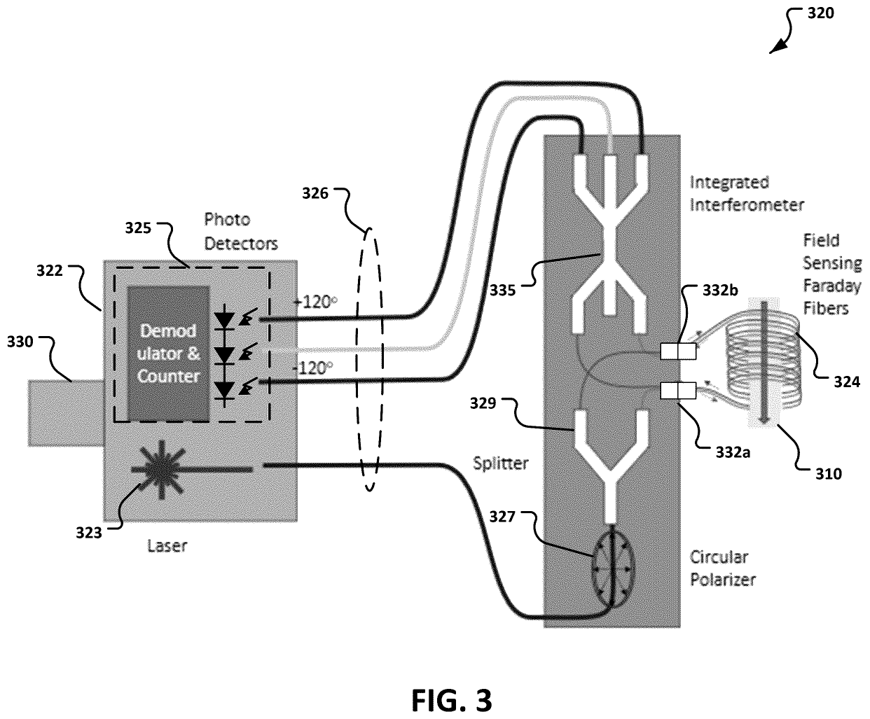

FIG. 3 is an example configuration of a probe 320 using circular polarized light and an interferometer to measure the differential phase shift between the forward and counter path fibers.

Probe 320 is similar to probe 220 from FIG. 2 in that it is configured for measuring a current in a DUT 310. Probe 320 includes a sensor head 324 that is similar to sensor head 224, and may include one or more pluggable interfaces 332a, 332b, which are similar to pluggable interfaces 232a, 232b. Probe 320 includes a probe body 322 enclosed in a housing, similar to probe body 222. Probe body 322 includes a connector 330, an optical source 323, and receive circuitry 325, which are respectively similar to connector 230, optical source 223, and receive circuitry 225. In probe 320, the optical source 323 produces the optical measurement signal, which is transmitted, through a source optical fiber of the transmission optical fibers 326 to a circular polarizer 327. The polarized optical measurement signal is then sent through a splitter 329, and the two outputs of the splitter are each fed into one of the two counter-wrapped sensor head optical fibers. The optical measurement signals have a polarization state modified by the current signal being measured in the DUT 310 as they traverse the sensor head, and are then fed into one side of an interferometer 335. In the example of FIG. 3, the interferometer is a 3×3 interferometer. The other side of the interferometer is coupled to the optical receiver(s) in the receive circuitry 325 by receive fibers of the transmission optical fibers 326.

In the example shown in FIG. 3, the 3×3 interferometer 335 enables the electronics in receive circuitry 325 to cancel detector offsets via the linear (gain and additions only) Clarke transformation before computing the arctangent. Note that the equation for I and Q only depend on the amplitude and phase from the detector, not the detector offsets from mid-scale.

$$[ \begin{matrix}I \\ Q \\ O\end{matrix} ] = [ \begin{matrix}\sqrt{2} A cos ( θ ) \\ \sqrt{2} A sin ( θ ) \\ Offset\end{matrix} ] = [ \begin{matrix}1 & - \frac{1}{2} & - \frac{1}{2} \\ 0 & \frac{\sqrt{3}}{2} & - \frac{\sqrt{3}}{2} \\ \frac{1}{2} & \frac{1}{2} & \frac{1}{2}\end{matrix} ] [ \begin{matrix}A cos ( θ + 120 ° ) + Offset \\ A cos ( θ ) + Offset \\ A cos ( θ - 120 ° ) + Offset\end{matrix} ]$$

$$\text{Where:}$$

$$I = inphase$$

$$Q = quadrature$$

The Offset includes both the average power and any offset in the detector, and need not be computed, but the sensor could use the measurement to normalize the I and Q if the detector offset is a small compared to the detector offset. The sensor can perform the normalization performed by computation or by adjusting the source power, potentially making the measurement of the Faraday effect phase shift easier.

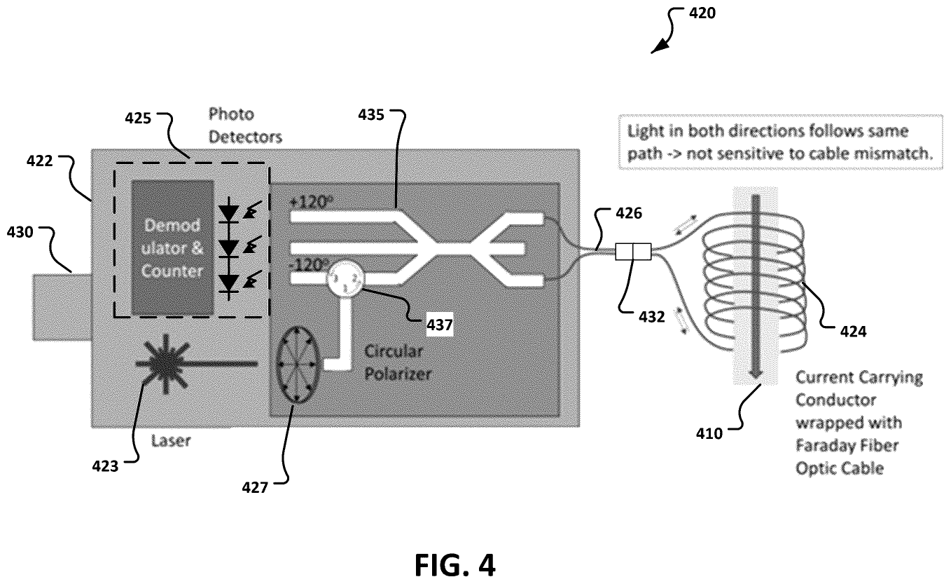

As shown in FIGS. 4-6, some embodiments of the disclosure may employ a Sagnac interferometer. In probes 420, 520, 620 shown in FIGS. 4-6, probe bodies 422, 522, 622 are similar to probe bodies 222, 322 from FIGS. 2 and 3. Connectors 430, 530, 630 are similar to connectors 230, 330, optical sources 423, 523, 623 are similar to optical sources 223, 323, and receive circuitry 425, 525, 625, is similar to receive circuitry 225, 325. Pluggable interfaces 432, 532, 632 are similar to pluggable interfaces 232a, 232b, 332a, 332b, except with a different number of optical connections. In the embodiments shown in FIGS. 4-6, the sensor head 424, 524, 624 includes a single sensor head optical fiber wrapped around a current-carrying conductor in the DUT 410, 510, 610. As shown in FIG. 4, a 3×3 Sagnac interferometer 435 sends the optical measurement signal from optical source 423 and circular polarizer 427 via transmission optical fibers 426 through the sensor head 424 optical fiber in both directions, thus eliminating any common mode signal from sending the sensing through two different fibers. This interferometer configuration allows for elimination of drift for precise DC measurements. In some embodiments, the probe 420 may also include an optical circulator 437 integrated into the interferometer 435.

The Sagnac Interferometer does not require a narrow band laser for the measurement; however, optical circulators and circular polarizers are band limited.

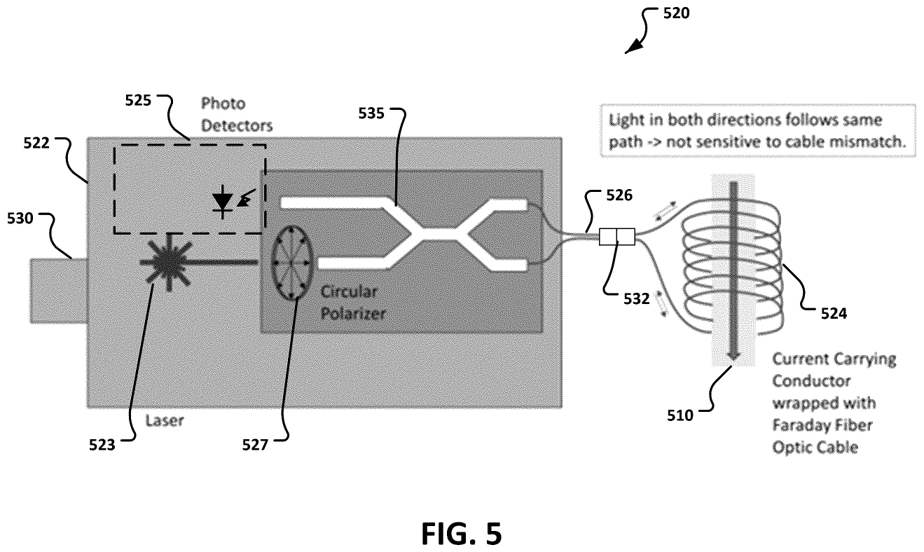

As shown in FIG. 5, in some embodiments, a 2×2 Sagnac interferometer 535 may be constructed without the optical circulator in a single output configuration; however, with only a single output, demodulation is impossible.

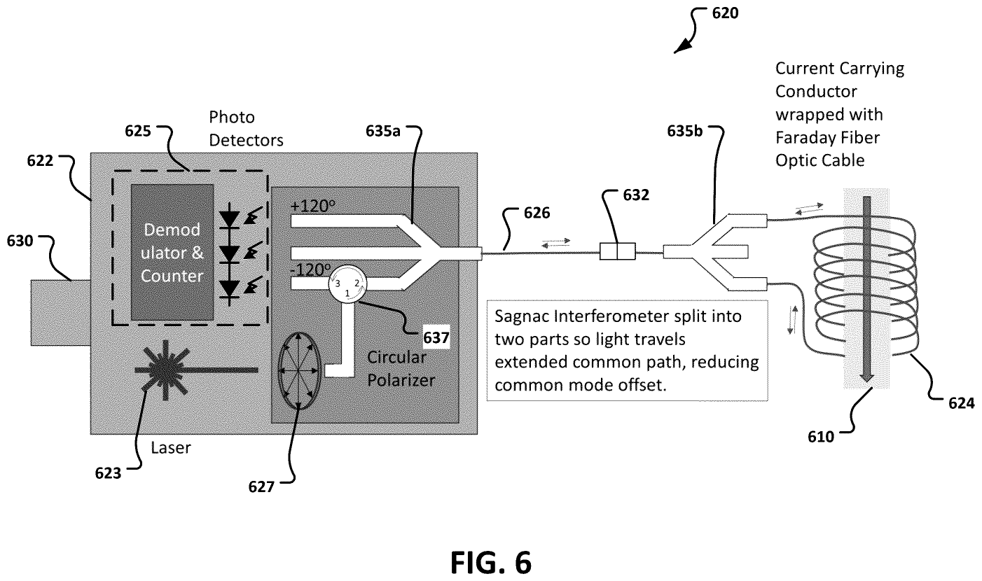

The embodiment of a probe 620 shown in FIG. 6, uses a similar configuration as the probe 420 shown in FIG. 4, except that in probe 620, the interferometer, a 3×3 Sagnac interferometer, is split into two portions 635a, 635b, with the first portion 635a being included in the probe body 622, and the second portion 635b being included in the sensor head 624. The pluggable interface 632 may be located between the first portion 635a and the second portion 635b. Splitting the interferometer into two portions causes the optical measurement signal to travel an extended common path, e.g. via transmission optical fibers 626, thereby reducing common mode offset.

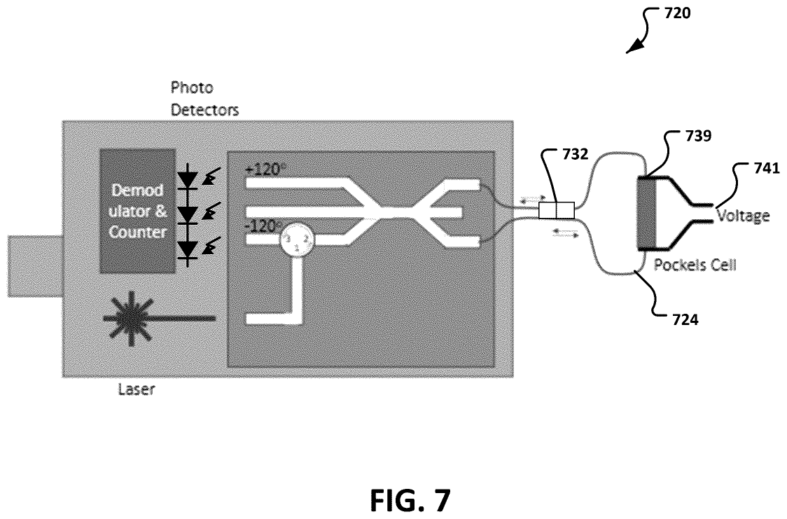

The discussion above has used the example application of probing and sensing/measuring a current in a DUT. Other embodiments of the disclosure include probes that can be used for sensing/measuring a voltage in a DUT. As illustrated in the example of probe 720 in FIG. 7, according to some embodiments, voltage sensing uses the same the interferometer discussed above with a Pockels cell, a crystal that is sensitive to voltage instead of current. The Er for the crystals are 10× that of the fiber, so optical matching is required for the connections of the fibers to the cell. One example type of crystal that can be used to construct the Pockel's cell is RTP—Rubidium Titanyl Phosphate. Thus, in probe 720, the sensor head 724 is a voltage sensor head, and the sensor head 724 includes one sensor head optical fiber that runs through a Pockels cell 739. The Pockels cell 739 is coupled to two leads 741 that a user can use to connect to a voltage signal in the DUT to be measured.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

What is claimed is:

1. A test and measurement probe for measuring an electrical signal in a device under test (DUT), the probe comprising:
a probe body enclosed in a housing, the probe body including
an optical source to produce an optical measurement signal,
receiver circuitry, including an optical receiver, to receive the optical measurement signal and convert the optical measurement signal to an electrical measurement signal, and
a connector to output the electrical measurement signal to an input of a test and measurement instrument;
a sensor head separate from the probe body, the sensor head including
one or more sensor head optical fibers configured to convey the optical measurement signal to cause the electrical signal in the DUT to modify a polarization state of the optical measurement signal;
one or more transmission optical fibers to convey the optical measurement signal between the probe body and the sensor head; and
a pluggable interface between the probe body and the sensor head.

2. The test and measurement probe according to claim 1, wherein the pluggable interface comprises one or more optical connectors between the one or more sensor head optical fibers and the one or more transmission optical fibers.

3. The test and measurement probe according to claim 2, wherein the one or more sensor head optical fibers have a first end and a second end, and the pluggable interface is located at one of the first end or the second end to allow a user of the probe to wrap the one or more sensor head optical fibers around a current-carrying conductor in the DUT.

4. The test and measurement probe according to claim 2, wherein the one or more sensor head optical fibers have a first end and a second end, and the pluggable interface is located at both of the first end and the second end to allow a user of the probe to wrap the one or more sensor head optical fibers around a current-carrying conductor in the DUT, and to fully disconnect the sensor head from the probe to leave the sensor head installed in the DUT.

5. The test and measurement probe according to claim 1, wherein the pluggable interface is keyed.

6. The test and measurement probe according to claim 1, wherein the pluggable interface includes a memory device to store at least one of gain data and calibration data.

7. The test and measurement probe according to claim 1, wherein the one or more sensor head optical fibers have different optical characteristics than the one or more transmission optical fibers.

8. The test and measurement probe according to claim 1, wherein the sensor head is a current sensor head, and the one or more sensor head optical fibers comprise a pair of sensor head optical fibers to be counter-wrapped around a current-carrying conductor in the DUT.

9. The test and measurement probe according to claim 8, further comprising a polarizer coupled to the optical source.

10. The test and measurement probe according to claim 9, wherein:
the polarizer is a linear polarizer; and
the one or more transmission optical fibers comprise a source optical fiber coupled to the optical source and four receive optical fibers coupled to the optical receiver;
the probe further comprising:
a first splitter coupled between the linear polarizer and the pair of sensor head optical fibers;
a second splitter coupled between one of the pair of sensor head optical fibers and a first pair of orthogonal linear polarizers, each coupled to one of the four receive optical fibers; and
a third splitter coupled between an other of the pair of sensor head optical fibers and a second pair of orthogonal linear polarizers, each coupled to one of the four receive optical fibers.

11. The test and measurement probe according to claim 9, wherein:
the polarizer is a circular polarizer; and
the one or more transmission optical fibers comprise a source optical fiber coupled to the optical source and three receive optical fibers coupled to the optical receiver;
the probe further comprising:
a first splitter coupled between the circular polarizer and the pair of sensor head optical fibers; and
a 3×3 interferometer coupled between the pair of sensor head fibers and the three receive optical fibers.

12. The test and measurement probe according to claim 1, wherein the sensor head is a current sensor head, and the one or more sensor head optical fibers comprise one sensor head optical fiber to be wrapped around a current-carrying conductor in the DUT.

13. The test and measurement probe according to claim 12, further comprising an interferometer coupled between the optical source, the sensor head optical fiber, and the optical receiver.

14. The test and measurement probe according to claim 13, further comprising a circular polarizer coupled between the optical source and the interferometer.

15. The test and measurement probe according to claim 14, further comprising an optical circulator integrated into the interferometer.

16. The test and measurement probe according to claim 13, wherein the interferometer comprises a 2×2 Sagnac interferometer.

17. The test and measurement probe according to claim 13, wherein the interferometer comprises a 3×3 Sagnac interferometer.

18. The test and measurement probe according to claim 13, wherein a first portion of the interferometer is included in the probe body housing, and a second portion of the interferometer is included in the sensor head.

19. The test and measurement probe according to claim 18, wherein the pluggable interface is located between the first portion of the interferometer and the second portion of the interferometer.

20. The test and measurement probe according to claim 1, wherein
the sensor head is a voltage sensor head;
the one or more sensor head optical fibers comprise one sensor head optical fiber including a Pockels cell; and
the Pockels cell is coupled to a pair of leads to be connected to a voltage signal in the DUT;
the probe further comprising:
an interferometer coupled between the optical source, the sensor head optical fiber, and the optical receiver.
